(19) United States
(12) Patent Application Publication
(10) Pub. No.: US 2024/0186445 A1
(43) Pub. Date: Jun. 6, 2024

(54) METHOD FOR POROSIFYING (Al,In,Ga)N/(Al,In,Ga)N MESAS

(71) Applicant: COMMISSARIAT A L'ENERGIE ATOMIQUE ET AUX ENERGIES ALTERNATIVES, Paris (FR)

(72) Inventors: Margaux AUDIBERT, Grenoble Cedex (FR); Carole PERNEL, Grenoble Cedex (FR); François LEVY, Grenoble Cedex (FR); Ilyes MEDJAHED, Grenoble Cedex (FR)

(73) Assignee: COMMISSARIAT A L'ENERGIE ATOMIQUE ET AUX ENERGIES ALTERNATIVES, Paris (FR)

(21) Appl. No.: 18/524,628

(22) Filed: Nov. 30, 2023

(30) Foreign Application Priority Data
Dec. 5, 2022 (FR) 22 12783

(51) Int. Cl. H01L 33/00; H01L 33/14; H01L 33/32

(52) U.S. Cl. CPC H01L 33/0075; H01L 33/14; H01L 33/32

(57) ABSTRACT

Method for porosifying mesas comprising the following steps:
providing a structure (100) comprising a substrate (110) covered with (Al,In,Ga)N/(Al,In,Ga)N mesas (120),
the substrate (110) comprising a support layer (114), a first layer of non-doped GaN (111) and a second layer of doped GaN (112),
the mesas (120) comprising a third layer of heavily doped (Al,In,Ga)N(123) and a fourth layer of non-doped or lightly doped (Al,In,Ga)N(124),
a part (112b) of the second layer (112) of doped GaN being extended in the mesas (120) or a part (123a) of the third layer (123) of heavily doped (Al,In,Ga)N being extended in the base substrate (110),
   immersing the structure (100) and a counter-electrode in an electrolytic solution,
   applying a voltage or a current between the structure (100) and the counter-electrode so as to porosify the third layer (123) of heavily doped (Al,In,Ga)N of the mesas (120).

### TECHNICAL FIELD

The present invention relates to the general field of colour microscreens. The invention relates to a method for porosifying (Al,In,Ga)N/(Al,In,Ga)N mesas. The invention also relates to a structure thus obtained comprising porosified (Al,In,Ga)N/(Al,In,Ga)N mesas. The invention finds applications in numerous industrial fields, and in particular in the field of colour microscreens based on micro-LEDs.

### PRIOR ART

Colour microscreens comprise pixels formed by blue, green and red subpixels (RGB pixels). In the remainder of the description, these subpixels will be referred to more simply as pixel for reasons of conciseness.

Blue and green pixels can be manufactured from nitride materials and red pixels from phosphide materials. To combine these three types of pixel on the same substrate, the so-called “pick and place” technique is generally used. However, in the case of microscreens with pixels of less than 10 μm, this technique can no longer be used because not only of problems of alignment but also the time necessary for implementing such a technique on this scale. For screens with a large number of pixels (high definition), this “pick and place” technique is problematic in terms of time. In addition it is necessary to take the pixels from different wafers, which requires successive transfers. Parallel-transfer techniques can also be used (“mass transfer”).

Another solution consists in converting colours with quantum dots (QD) or nanophosphors pumped by blue pLEDs coming from a single wafer, either transferred or in a monolithic matrix (the preferred case for microscreens). However, controlling the deposition of these materials on small pixels is difficult and their resistance to creep is not sufficiently robust.

It is therefore crucial to be able to obtain the three RGB pixels natively with the same family of materials and the growth of which is implemented on the same substrate. For this purpose, InGaN is the most promising material. This material can in fact theoretically cover the entire visible spectrum depending on its concentration of indium. Blue micro-LEDs based on InGaN already show high luminance, much superior to their organic homologues. To emit at wavelengths in the green, the quantum wells (QWs) of the LED must contain at least 25% indium and, for emission in the red, it is necessary to have at least 35% indium. Unfortunately, the quality of the InGaN material beyond 20% In is degraded because of the low miscibility of InN in GaN, but also because of the high compressive stress inherent in the growth of the InGaN active region on GaN.

It is therefore essential to be able to reduce the overall stress in structures based on GaN/InGaN.

Currently, one of the most promising solutions consists in porosifying the layer of GaN, as described for example in the articles by Pasayat et al. (Materials 2020, 13, 213; Appl. Phys. Lett. 116 111101 (2020)). The method described in these articles comprises the following steps:
providing a stack comprising a sapphire substrate covered by a layer of not intentionally doped GaN (nid GaN), a layer of Si n+ doped GaN (5×10¹⁸ at/cm³) and a layer of InGaN or of not intentionally doped GaN,
partially etching the stack to form the GaN/InGaN or GaN/GaN mesas; the thickness of the doped layer is only partially etched so that the residual doped layer at the mesa bottom allows polarisation of the doped layer of all the mesas (“ring polarisation” or wafer edge polarisation, for example),
implementing an electrochemical porosification step in a solution of oxalic acid (0.3 M), the layer of doped GaN fulfilling the role of anode and a platinum wire fulfilling the role of cathode.

The porosified layer of GaN thus obtained can make it possible to grow a nitride LED structure based on InGaN of better crystalline quality, thanks to the relaxation of the porous mesas generated.

However, the quality of the LED depends not only on the diameter of the pores and the porosity of the porosified layer of GaN. It is therefore necessary to be able to homogeneously porosify all the mesas of one and the same wafer.

It is also possible to have a layer common to all the mesas in these stacks. The porosification step is then implemented by polarising this common layer with an anodic potential.

For example, FIGS. 1A to 1C show various steps of such a method. More particularly, the method comprises the following steps:
providing a stack comprising successively a support layer 10, a not intentionally doped (nid) GaN layer 11, a doped or heavily doped GaN layer 12, and a layer of InGaN or of nid GaN 13 (FIG. 1A),
structuring mesas in this stack, the mesas comprising the layer of InGaN or of nid GaN 13 and a part of the doped or heavily doped GaN layer 12 (FIG. 1B), the other part of the doped GaN layer fulfilling the role of layer common to the mesas,
immersing the structure obtained in an electrolytic solution and applying a voltage between the doped or heavily doped GaN layer 12 and a counter-electrode, by means of which a porosified GaN layer 12′ is obtained (FIG. 1C).

It is known that layers of nid InGaN have intrinsic defects (‘V-pits’), which facilitates the porosification of the mesas since the electrolytic solution can infiltrate from this top layer 13 of the mesas to the doped or heavily doped layer 12 through these defects at the same time as by the sides of the doped or heavily doped layer of the mesas 12.

However, the layers of nid GaN do not have such defects: these are dense layers. Thus, in the GaN/GaN configuration, the doped or heavily doped layer of the mesas 12 porosifies from the sides of the mesas to the centre of the mesas. This layer cannot fully porosify to the centre of the mesas. Edge/centre effects of the wafer are observed, for example on 2-inch wafers. This effect may be due to the degradation of the lateral conductivity of the residual mesa-bottom doped layer, the polarisation taking place through the periphery of the wafer, and hence the wafer edge/centre effect.

There is therefore a real need to have a method for fully porosifying the mesas and limiting the edge/centre effects on the wafers, in particular on 2-inch (5.08 cm) wafers and all the more so on larger wafers (200 mm and 300 mm).

### DESCRIPTION OF THE INVENTION

One aim of the present invention is to propose a method for porosifying (Al,In,Ga)N/(Al,In,Ga)N mesas making it possible to porosify not only the whole volume of the doped GaN layer of the mesas, but also to identically (or homogeneously) porosify all the mesas on the wafer, whether at the edge or at the centre of the wafer, the method having to be advantageously usable even for large substrates (typically on substrates at least 5 cm and preferably at least 10 cm in diameter).

For this purpose, the present invention proposes a method for porosifying (Al,In,Ga)N/(Al,In,Ga)N mesas comprising the following steps:
a) providing a structure comprising a base substrate covered with (Al,In,Ga)N/(Al,In,Ga)N mesas,
   the base substrate comprising a support layer, a first layer of non-doped GaN and a second layer of doped GaN,
   the (Al,In,Ga)N/(Al,In,Ga)N mesas comprising a third layer of heavily doped (Al,In,Ga)N and a fourth layer of non-doped or lightly doped (Al,In,Ga)N,
   a part of the second layer of doped GaN being extended in the mesas or a part of the third layer of heavily doped (Al,In,Ga)N being extended in the base substrate,
b) electrically connecting the structure (for example at the second doped layer, at the third heavily doped layer or at the fourth lightly doped layer) and a counter-electrode to a voltage or current generator,
c) immersing the structure and the counter-electrode in an electrolytic solution,
d) applying a voltage or a current between the structure and the counter-electrode so as to porosify the third layer of heavily doped (Al,In,Ga)N of the mesas.

The invention is fundamentally distinguished from the prior art by the presence of a bilayer comprising two layers based on doped GaN having different dopings (the second layer made of doped GaN and the third layer made of heavily doped (Al,In,Ga)N). The bilayer is positioned between the first non-doped GaN layer of the substrate and the fourth non-doped or lightly doped (Al,In,Ga)N layer of the mesas.

The second layer has a doping level less than that of the third layer, and can serve to make the electrical contact. By virtue of a porosification selectivity according to the doping, the second layer is not porosified during step d) and remains integral until the end of the process of porosifying the mesas, which makes it possible to porosify all the mesas in volume whatever their position in the structure. It is thus possible to porosify the third layer of heavily doped (Al,In,Ga)N without excessively increasing the thickness of the stack, in particular in the case of a silicon substrate.

Advantageously, for the second layer, a sufficiently light doping will be selected for the layer not to be porosified, while being sufficiently high to ensure electrical conduction. For example, the doping level of the second doped GaN layer is less than 5×10¹⁸ at/cm³, preferably between 5×10¹⁷ at/cm³ and 3×10¹⁸ at/cm³, even more preferentially between 5×10¹⁷ at/cm³ and 2×10¹⁸ at/cm³. Such a doping level is for example obtained with silicon doping. It is also possible to have doping with germanium. The doping can then be higher, for example up to 5×10¹⁸ at/cm³, or even up to 1.5×10¹⁹ at/cm³.

Advantageously, the doping of the third layer is appreciably greater than that of the second layer, to obtain selectivity with respect to porosification. The greater the difference in doping between the second doped layer and the third heavily doped layer, the better the selectivity of the porosification process. The appropriate doping values depend on the potential applied for the porosification selectivity. For example, the doping level of the third layer of heavily doped (Al,In,Ga)N is between 5×10¹⁸ at/cm³ and 2×10¹⁹ at/cm³, more preferentially between 6×10¹⁸ at/cm³ and 2×10¹⁹ at/cm³, even more preferentially between 8×10¹⁸ at/cm³ and 1.5×10¹⁹ at/cm³, even more preferentially between 8×10¹⁸ at/cm³ and 1×10¹⁹ at/cm³ for example with an Si or Ge doping. It is possible to have doping levels up to 1×10²⁰ at/cm³ or even 1×10²¹ at/cm³ with a Ge doping.

According to a particularly advantageous embodiment, the structure furthermore comprises an additional layer of heavily doped GaN disposed between the first non-doped GaN layer and the third doped (Al,In,Ga)N layer. Here it will be understood that the doping level of the heavily doped GaN of the additional layer is higher than that of the first layer of non-doped GaN and higher than that of the third layer of doped (Al,In,Ga)N. There is thus a trilayer comprising an additional layer of heavily doped GaN covered by the second doped layer and the third heavily doped layer to be porosified. The trilayer is positioned between the first non-doped GaN layer of the substrate and the fourth non-doped or lightly doped (Al,In,Ga)N layer of the mesas.

Since the second doped layer entirely covers the additional layer, it provides protection of the underlying heavily doped additional layer from any porosification, and also ensures making contact. Advantageously, this layer is fine (typically between 200 nm and 1 μm, preferentially between 400 and 700 nm. This layer is advantageously the finest possible while remaining properly covering to avoid infiltration of the electrolyte and therefore consumption of the heavily doped underlying additional layer during step d).

The heavily doped additional layer provides the lateral conduction of the charges in the structure. For example, the doping level of the additional layer of heavily doped GaN is between 5×10¹⁸ at/cm³ and 2×10¹⁹ at/cm³, preferably between 5×10¹⁸ at/cm³ and 1.5×10¹⁹ at/cm³, even more preferentially between 8×10¹⁸ at/cm³ and 1×10¹⁹ at/cm³. Advantageously, this layer is thick (typically between 0.5 μm and 5 μm and preferably between 1 and 2 μm. Greater thicknesses can be obtained on sapphire. In this way a highly conductive buried layer is obtained by virtue of the high doping level and a great thickness of layer. The thickness/doping pair will be adapted to have sufficient lateral conduction. During step d), the conduction takes place via this heavily doped buried additional layer. As it is highly conductive, it limits the edge/centre effects.

The charges pass through the doped second layer and are then located on the heavily doped additional layer, which then fulfils the role of conduction highway and supplies all the mesas present on the substrate. During step d), the second doped layer protects the heavily doped additional layer from porosification. Thus each mesa is in the same electrical configuration for being porosified uniformly whatever the size and position of the mesa on the wafer (edge or centre).

Advantageously, the doping level of the third layer of heavily doped (Al,In,Ga)N and/or the doping level of the additional layer of heavily doped GaN is between 5×10¹⁸ at/cm³ and 1.5×10¹⁹ at/cm³.

Advantageously, the voltage applied during step e) is between 3 V and 15 V, preferably between 6 V and 12 V, even more preferentially between 8 V and 12 V, and even more preferentially between 8 and 10 V.

Advantageously, the support layer is a wafer at least 5 cm in diameter, for example 2 inches, i.e. 5.08 cm), preferably at least 100 mm in diameter and even more preferentially at least 200 mm in diameter.

Advantageously, the support layer is made from sapphire or silicon.

Advantageously, the fourth layer of non-doped or lightly doped (Al,In,Ga)N is a layer of GaN.

At the end of step d), LEDs can then be formed, for example by epitaxy, on the mesas to form pixels.

The method has numerous advantages:
it is simple to implement,
it can be applied to large wafers to manage the problem of uniformity of electrochemical polarisation and therefore of porosification/relaxation,
it is compatible with the use of Si (111) substrates for the growth, more sensitive to deformation than sapphire, the strong doping of the buried layer making it possible to reduce its thickness,
preservation of the porosification of the mesa bottoms allows better control of the epitaxy of InGaN, in particular in the case of selective epitaxy, the growth mask on the non-porous mesa bottoms favouring mobility of the species towards the growth sites,
it can be used for mesas of different sizes, including thin mesas.

In addition, growth on such porous mesas has the following advantages:
structuring in a mesa provides the effect of elastic compliance, including during growth,
it leads to partial or total relaxation of the stresses and reduces the piezoelectric polarisation by comparison with a stress layer with the same concentration of In,
it allows a so-called “bottom-up” approach for the ρLED and ρdisplay manufacture: the optical structures (N, QW, P) are grown after pixelation in mesas, whatever the size of the pixels, and makes it possible to dispense with the problems of alignment as with the “pick and place” method,
there is no impact of the pixel etching method on the efficacy of the micro-LEDs, which makes it possible to produce a micrometric or sub-micrometric pixel.

The invention also relates to a structure obtained according to the previously described method.

The structure comprises a base substrate covered with porosified (Al,In,Ga)N/(Al,In,Ga)N mesas,
the base substrate comprising a support layer, a first layer of non-doped GaN and a second layer of doped GaN,
the (Al,In,Ga)N/(Al,In,Ga)N mesas comprising a third layer of heavily doped and porosified (Al,In,Ga)N and a fourth layer of non-doped or lightly doped (Al,In,Ga)N,
a part of the second layer of GaN furthermore being able to be extended in the mesas.

Advantageously, the structure furthermore comprises an additional layer of heavily doped GaN disposed between the first non-doped GaN layer and the second doped GaN layer.

Advantageously, the fourth layer of non-doped or lightly doped (Al,In,Ga)N is a layer of GaN and/or the support layer is a 2-inch wafer or a wafer at least 100 mm in diameter and preferably a wafer at least 200 mm in diameter.

Other features and advantages of the invention will become apparent from the following additional description.

It goes without saying that this additional description is given only as an illustration of the object of the invention and should in no way be interpreted as a limitation of this object.

### BRIEF DESCRIPTION OF THE DRAWINGS

The present invention will be better understood upon reading the description of example embodiments given merely for indication and without limitation, with reference to the appended drawings wherein:

FIGS. 1A to 1C, described previously, show, schematically, various steps of a porosification method according to the prior art;

FIGS. 2A and 2B and FIGS. 3A and 3B show, schematically and in cross-section, various structures comprising (Al,In,Ga)N/(Al,In,Ga)N mesas according to various embodiments of the invention;

FIG. 4 is a graph showing various phenomena (pre-porosification (or “pre-breakdown” porosification) and electropolishing) involved in an anodising step, as a function of the doping level of a layer of GaN and the voltage applied, according to a particular embodiment of the invention; region A corresponds to the pre-porosification (or “pre-breakdown” porosification) region, region B to the porosification region, region B′ to the transient region between regions B and C, where the pores join and coalesce, and region C to the electropolishing region;

FIG. 5 shows, schematically and in cross section, a structure comprising (Al,In,Ga)N/(Al,In,Ga)N mesas (in particular GaN/GaN) used comparatively;

FIG. 6 is a photograph obtained with a scanning electron microscope of an (Al,In,Ga)N/(Al,In,Ga)N mesa of the structure shown on FIG. 5 after the porosification step, which leads to incomplete porosification;

FIGS. 7A and 7B are photographs obtained with a black-background optical microscope of various (Al,In,Ga)N/(Al,In,Ga)N mesas, in plan view, of the structure shown on FIG. 5 after the porosification step, respectively at the centre and at the edge of the structure; the left-hand part of the figures corresponds to (Al,In,Ga)N/(Al,In,Ga)N mesas 3 μm wide and the right-hand part of the figures corresponds to (Al,In,Ga)N/(Al,In,Ga)N mesas 5 μm wide;

FIG. 8 is a photograph obtained with a black-background optical microscope of (Al,In,Ga)N/(Al,In,Ga)N mesas 3 μm wide (on the left) and of (Al,In,Ga)N/(Al,In,Ga)N mesas 5 am wide (on the right), in plan view, after the porosification step according to various particular embodiments of the invention; the photograph is taken at the centre of the structures (i.e. furthest away from the electrical contact that is made at the edge of the wafer, i.e. at the centre which is the place where the loss of potential is the greatest);

FIG. 9 is a photograph obtained with a black-background optical microscope of (Al,In,Ga)N/(Al,In,Ga)N mesas 3 μm wide (on the left) and of (Al,In,Ga)N/(Al,In,Ga)N mesas 5 μm wide (on the right), in plan view, after the porosification step according to various particular embodiments of the invention; the photograph is taken at the centre of the structures;

FIGS. 10A and 10B are photographs obtained with a scanning electron microscope of an (Al,In,Ga)N/(Al,In,Ga)N mesa porosified according to a particular embodiment of the invention;

FIGS. 11A and 11B are simulations representing the current densities in a structure comprising (Al,In,Ga)N/(Al,In,Ga)N mesas during a 12 V porosification step, according to a particular embodiment of the invention.

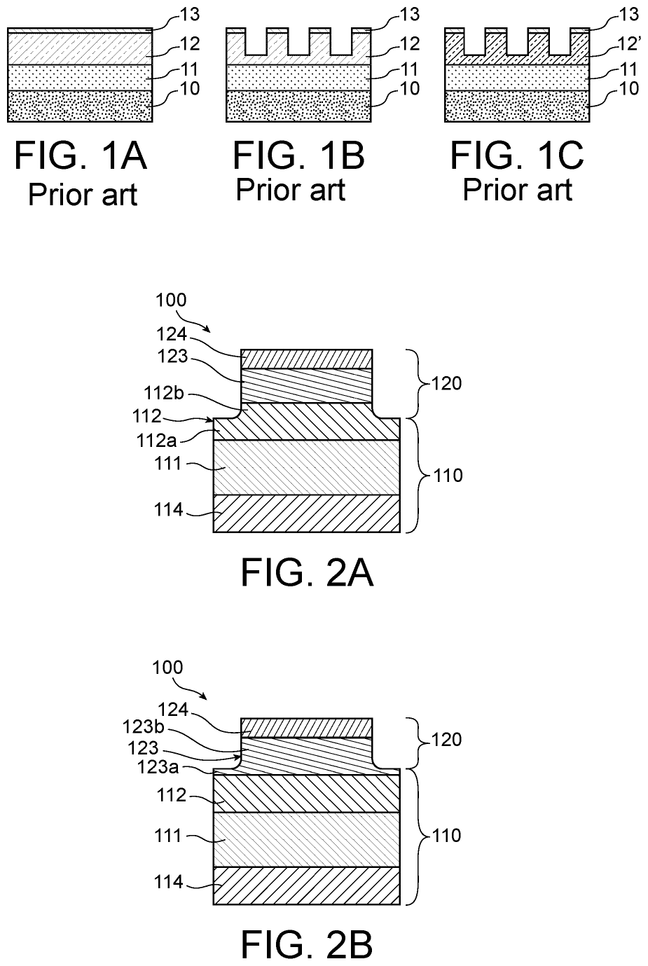

### DETAILED DESCRIPTION OF PARTICULAR EMBODIMENTS

The different parts shown in the figures are not necessarily plotted according to a uniform scale, to make the figures more readable.

The various possibilities (alternatives and embodiments) must be understood as not being mutually exclusive and can be combined with one another.

Furthermore, in the description hereinafter, terms that depend on the orientation, such as “top”, “bottom”, etc., of a structure apply while considering that the structure is oriented as illustrated in the figures.

Although this is by no means limiting, the invention particularly has applications in the field of colour microscreens, and more particularly for manufacturing red green blue pixels. However, it could be used in the photovoltaic or water electrolysis (“water splitting”) field since, firstly, InGaN absorbs throughout the visible spectrum and, secondly, its valency and conduction bands are around the water stability domain, the thermodynamic condition necessary for the water decomposition reaction. The invention can also be advantageous in the manufacture of LEDs or lasers emitting at long wavelength.

The method is particularly advantageous for manufacturing structures comprising porosified (Al,In,Ga)N/(Al,In,Ga)N mesas having in particular a pitch of less than 30 μm.

(Al,In,Ga)N means AlN, AlGaN, InGaN or GaN. Hereinafter, reference is more particularly made to porous GaN but, with such a method, it is possible to have, for example, porous InGaN or AlGaN. The dense layer of InGaN (under compression) or the dense layer of AlGaN (under tension) will relax by virtue of a porous structure whatever its composition.

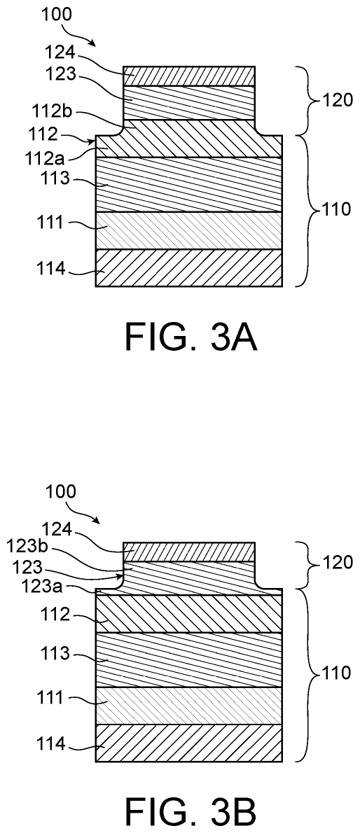

The method for porosifying (Al,In,Ga)N/(Al,In,Ga)N mesas 120 comprises the following steps:
a) providing a structure 100 comprising a base substrate 110 covered with (Al,In,Ga)N/(Al,In,Ga)N mesas 120 (FIGS. 2A, 2B, 3A, 3B),
   the base substrate 110 comprising successively:
      a support layer 114,
      optionally a buffer layer of (Al,Ga)N, in particular in the case of a silicon support layer 114,
      a first layer 111 of non-doped GaN,
      advantageously, a heavily doped additional layer 113,
      a second layer 112 of doped GaN,
   the (Al,In,Ga)N/(Al,In,Ga)N mesas 120 comprising:
      a third layer 123 of heavily doped (Al,In,Ga)N, intended to be porosified, and
      a fourth layer 124 of non-doped or lightly doped (Al,In,Ga)N,
   a part of the second layer of doped GaN being extended in the mesas or a part of the third layer of heavily doped (Al,In,Ga)N being extended in the base substrate, the bottom of the mesas is preferably preserved from porosification during step d),
b) electrically connecting the structure 100 and a counter-electrode to a voltage or current generator,
c) immersing the structure 100 and the counter-electrode in an electrolytic solution,
d) applying a voltage or a current between the second layer 112 of doped GaN and the counter-electrode so as to porosify the third layer 123 of heavily doped (Al,In,Ga)N of the mesas 120.

The structure 100 provided at step a) is for example obtained by providing and then locally etching a stack comprising successively:
a support layer 114,
optionally a buffer layer of (Al,Ga)N, in particular in the case of a silicon support layer 114,
a first layer 111 of non-doped gallium nitride GaN,
optionally, an additional layer 113 of heavily doped GaN,
a second layer 112 of doped GaN (GaN:n),
a third layer 123 of heavily doped (Al,In,Ga)N(GaN n+ or GaN n++), and
a fourth layer 124 of AlN, InGaN or GaN (denoted Al,In,Ga)N, not intentionally doped (nid) or lightly doped.

Preferably, the stack consists of the previously mentioned layers. In other words, it does not include other layers.

According to an advantageous embodiment, a first part 112a of the second layer 112 forms part of the base substrate 110 and a second part 112b of the second layer 112 forms part of the mesas 120 (as shown on FIGS. 2A and 3A).

The mesas 120 formed by etching the fourth layer 124, the third layer 123 and a first part 112a of the second doped layer 112 (FIGS. 2A and 3A). By stopping the etching in the doped layer, the entire height of the third n++ layer 123 is available for relaxation.

Each mesa 120 comprises successively from the base: the second part 112b of the layer 112 of doped GaN, the third layer 123 of heavily doped (Al,In,Ga)N and the fourth layer 124 of non-doped or weakly doped (Al,In,Ga)N.

The first part 112a of the second layer 112 of doped GaN protects the additional layer 113 during the porosification step. Thus the additional layer 113 is not in contact with the solution. The first part of the doped GaN layer is a layer common to all the mesas.

According to another embodiment, the mesas 120 are formed by etching the fourth layer 124 and a part of the heavily doped third layer 123 (FIGS. 2B and 3B). The n++ doped layer 123 is not completely etched, thus preserving the integrity of the n-GaN layer. This embodiment is particularly advantageous for protecting the buried n++ doped layer 113 (FIG. 3B). A first part 123a of the layer 123 is in the base substrate 110 and a second part 123b of the layer 123 forms part of the mesas 120.

The stack is, for example, structured by photolithography.

Thus a structure 100 comprising a base substrate 110 surmounted by a plurality of (Al,In,Ga)N/(Al,In,Ga)N mesas 120 is obtained.

The mesas 120, also called elevations, are elements in relief. They are obtained, for example, by etching a continuous layer or a plurality of superimposed continuous layers, so as to leave only a certain number of “reliefs” of this layer or layers. The etching is preferably implemented with a hard mask, for example SiO₂. After etching the mesas, this hard mask is removed by a wet chemical method before porosification. It is also possible to remove this hard mask after porosification, removing it solely in the regions serving for polarisation, for the electrochemical polarisation. Advantageously, the mask is removed after the porosification step.

Preferably, the sides of the mesas 120 are perpendicular to this stack of layers.

The surface of the mesas can be circular, hexagonal, square or rectangular.

The largest dimension of the surface of the mesas 120 ranges from 500 nm to 500 μm. For example, the largest dimension of a circular surface is the diameter.

The thickness of the mesas corresponds to the dimension of the mesa perpendicular to the underlying stack.

The spacing between two consecutive mesas 120 ranges from 50 nm to 20 μm.

The mesas 120 can have identical or different dopings. The higher the doping level, the greater will be the porosification at fixed potential. The relaxation of the fourth layer 124 of dense (Al,In,Ga)N depends on the degree of porosification of the mesas. Thus various quantities of indium can be incorporated during the re-epitaxy of InGaN on the dense layer 124 (by virtue of the reduction in the “compositional pulling effect” (i.e. the pushing of the atoms of In towards the surface, preventing them from being incorporated in the layer). In this way, after epitaxy of the complete LED structure, blue, green and red (RGB) mesas will be obtained on one the same substrate, and in a single growth step, if the difference between the relaxation levels of the mesas is sufficient.

The support layer 114 is for example made from sapphire or silicon.

The support layer 114 has for example a thickness ranging from 250 μm to 2 mm. The thickness depends on the nature of the support layer 114 and the dimensions thereof. For example, for a sapphire support layer 2 inches in diameter, the thickness can be 350 μm. For a sapphire support layer 6 inches in diameter, the thickness can be 1.3 mm. For a silicon support layer 200 mm in diameter, the thickness can be 1 mm.

In the case of a silicon support layer 114, a buffer layer of (Al,Ga)N is advantageously interposed between the support layer 114 and the nid GaN layer 111.

The first layer 111 is a layer of nid GaN. It is a not intentionally doped (nid) layer so as not to be porosified. Not intentionally doped GaN means a concentration of less than 5×10¹⁷ at/cm³.

The first layer 111 of nid GaN has for example a thickness ranging from 500 nm to 5 μm. Advantageously, its thickness is between 1 and 4 am to absorb the stresses related to the difference in mesh between the GaN and the substrate.

The second layer 112 is a layer of doped GaN. Doped GaN means a concentration greater than 5×10¹⁷ at/cm³, preferably greater than 1018 at/cm³, preferably between 1×10¹⁸ at/cm³ and 5×10¹⁸ at/cm³.

The second layer 112 of GaN has for example a thickness ranging from 200 nm to 1 μm, preferentially between 400 and 700 nm. It must be sufficiently electrically conductive to be able to achieve a resumption of contact on this layer during the electrochemical anodising step. The minimum thickness varies according to the doping level. This electrically conductive layer is electrically connected to the voltage or current generator.

The third layer 123 is a layer of heavily doped GaN. Heavily doped GaN means a concentration greater than 5×10¹⁸ at/cm³, preferably greater than 8×10¹⁸ at/cm³, or even greater than 10¹⁹ at/cm³. It has for example a doping ten times higher than the second layer 112. It has a thickness of between 200 nm and 2 μm. Preferably from 500 nm to 1 μm.

The fourth layer 124 is a not intentionally doped or lightly doped (Al,In,Ga)N layer. Lightly doped (Al,In,Ga)N means a doping between 5×10¹⁷ at·cm³ and 2×10¹⁸ at·cm³. Non-doped means a doping level of less than 5×10¹⁷ at/cm³.

This may be a layer of AlN, AlGaN, InGaN or GaN. It has for example a thickness of between 10 nm and 200 nm, preferably between 50 and 200 nm. The doping is sufficiently light for this layer to be electrically insulating. It is not porosified during step d).

This layer 124 is not or little impacted by the porosification and serves as a seed for resumption of growth. This layer 124 is continuous to ensure quality of the re-epitaxed layer, of a layer of (In,Ga)N for example, on the structure.

The additional layer 113 has a thickness of between for example 500 nm and 5 μm, preferably between 1 μm and 5 μm. Preferably, it has a doping concentration greater than 8×10¹⁸ at·cm³, or even greater than 1019 at·cm³, for example 1.5×10¹⁹ at·cm³. The additional layer 113 of heavily doped GaN can have a doping identical to or different from that of the third layer of heavily doped GaN. The additional layer 113 of heavily doped GaN can have a thickness identical to or different from that of the third layer of heavily doped GaN. Preferably, it has a thickness greater than that of the third layer to ensure good mobility of the charges.

The dopings of the various aforementioned layers, and particularly of the second layer 112, of the third layer 123 and of the additional layer 113, will be selected according to the voltage applied during porosification.

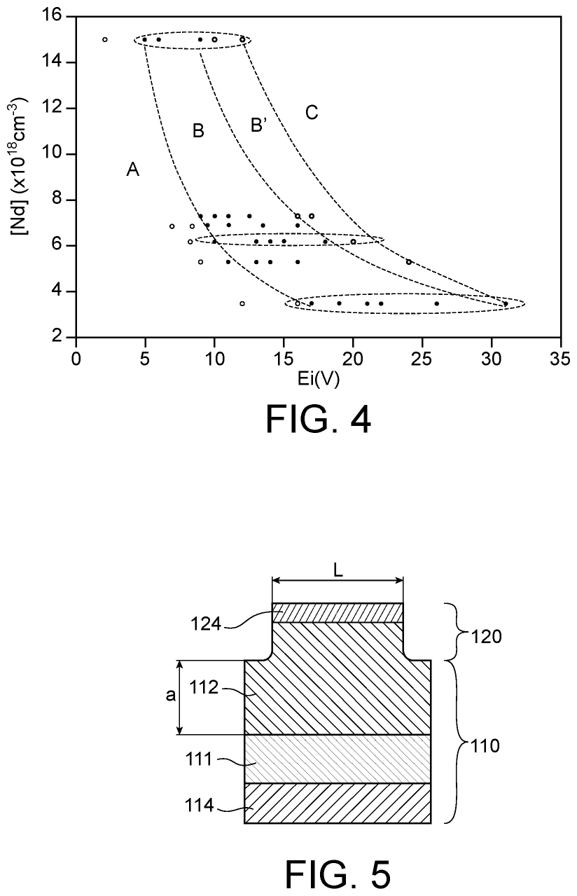

In particular, they will be selected from the “abacus” in FIG. 4. This “abacus” makes it possible to define the respective doping levels for, at a given potential, there to be selectivity between the heavily doped region and the lightly doped region. For a given potential, the doping level of the second layer 112 must the located in region A for the second layer 112 not to be porosified during step d), and the doping level of the third layer 123 must be located in region B for the third 123 to be porosified during step d).

Hereinafter, a type n doping is described, but it could be a case of a type p doping.

By way of illustration and non-limitatively, according to a variant embodiment, the structure 100 can comprise:
a base substrate 110 comprising successively: a sapphire or silicon support layer 114, optionally a buffer layer of (Al,Ga)N, a 4 am first layer 111 of non-doped GaN, a first part 112a of the 500 nm second layer 112 of doped GaN (1×10¹⁸ at/cm³),
(Al,In,Ga)N/(Al,In,Ga)N mesas 120 comprising successively: a second part 112b of the 100 nm second layer 112 of doped GaN (1×10¹⁸ at/cm³), an 800 nm third layer 123 of heavily doped GaN (1×10¹⁹ at/cm³), and a 100 nm layer of nid (Al,In,Ga)N.

According to another variant embodiment, the structure 100 can comprise:
a base substrate 110 comprising successively: a sapphire or silicon support layer 114, optionally a buffer layer of (Al,Ga)N, a 4 am first layer 111 of non-doped GaN, a 2 am additional layer 113 of heavily doped GaN (1×10¹⁹ at/cm³), a first part 112a of the 500 nm second layer 112 of doped GaN (1×10¹⁸ at/cm³),
(Al,In,Ga)N/(Al,In,Ga)N mesas 120 comprising successively: a second part 112b of the 100 nm second layer 112 of doped GaN (1×10¹⁸ at/cm³), an 800 nm third layer 123 of heavily doped GaN (1×10¹⁹ at/cm³), and a 100 nm fourth layer 124 of nid (Al,In,Ga)N.

During step b), the structure 100 and a counter-electrode (CE) are electrically connected to a voltage or current generator. The device fulfils the role of working electrode (WE). Hereinafter, it will be called a voltage generator, but it could be a current generator for applying a current between the device and the counter-electrode.

The contact is made on the structure 100.

In particular, the contact can be made on the base substrate 110. As shown on FIGS. 2A, 2B, 3A and 3B, the contact can be made on the second layer 112 of doped GaN (the contact is represented by an arrow on FIGS. 2A, 2B, 3A and 3B). The contact can be made on the bottom of the mesas, at the second layer 112, which makes it possible to use the etching step also to make the contacts.

It is also possible to make contact on one of the other layers: on the fourth layer 124 of lightly doped (Al,In,Ga)N, on the third layer 123 of heavily doped (Al,In,Ga)N or on the additional layer 113 of heavily doped GaN. In the case of making contact on a heavily doped layer its opening will advantageously be limited to a region preserved from the electrolyte.

The contacting region can also be surmounted by a metal layer in order to improve the contact for the electrochemical polarisation. This contact can be removed after the porosification before the epitaxial regrowth.

The counter-electrode 500 is made from an electrically conductive material, such as for example a metal with a large developed surface and inert to the electrolyte chemistry, such as a platinum grille.

During step c), the electrodes are immersed in an electrolyte, also referred to as an electrolytic bath or electrolytic solution. The electrolyte can be acidic or basic. The electrolyte is for example oxalic acid. It can also be KOH, HF, HNO₃, NaNO₃, or H₂SO₄.

During step d), a voltage is applied between the structure 100 and the counter-electrode 500. The voltage can range from 1 to 30 V for example. Preferably, it is from 5 to 15 V, and even more preferentially from 6 to 12 V, for example from 8 to 10 V. The voltage is selected according to the doping levels of the various layers, in order to obtain the required selectivity. It is applied for example for a period ranging from a few seconds to several hours. Porosification is complete when there is no longer any current at imposed potential. At this moment, all the doped structure is porosified and the electrochemical reaction stops.

The electrochemical anodising step can be implemented under ultraviolet (UV) light.

Advantageously, the porosification takes place throughout the volume of the third layer 123 of heavily doped (Al,In,Ga)N.

At the end of the porosification step, the degree of porosity of the third layer 123 of heavily doped (Al,In,Ga)N is advantageously at least 10%. It preferably ranges from 25% to 70%, preferably from 25% to 50%, for example from 45% to 50%.

The largest dimension (the height) of the pores can vary from a few nanometres to a few micrometres. The smallest dimension (the diameter) can vary from a few nanometres to around hundred nanometres, in particular from 30 to 70 nm.

The porosification obtained (degree of porosity and pore size) depends on the doping of the layer and the parameters of the method (voltage applied, duration, nature and concentration of the electrolyte, chemical post-treatment or annealing). Varying the porosification makes it possible to control the degree of incorporation/segregation. The porosification, and in particular the pore size, can vary subsequently, during the epitaxial regrowth, according to the temperature applied.

Advantageously, the method comprises a subsequent step e) during which epitaxy is implemented on the mesas 120, by means of which an at least partially relaxed, and preferably completely relaxed, epitaxed layer is obtained.

The relaxation percentage corresponds to: Δa/a=(a_{c2}−a_{c1})/a_{c1}, with a_{c1} the mesh parameter of the starting layer on which epitaxy is resumed (i.e. the mesh parameter of the layer 124), and a_{c2} the mesh parameter of the relaxed layer.

The layer is 100% relaxed if a_{c2} corresponds to the mesh parameter of the solid material, with the same composition as the re-epitaxed layer. When a_{cl}=a_{c2}, the layer is said to be stressed.

Partially relaxed means a relaxation percentage greater than 50%.

Epitaxial regrowth can serve for example to form re-epitaxed LEDs.

Epitaxial regrowth is implemented on the fourth layer 124 of nid or lightly doped (Al,In,Ga)N/(Al,In,Ga)N of the mesas 120. As this layer is not porosified during the electrochemical anodising step, it remains continuous and dense. Epitaxial regrowth is thus facilitated and the epitaxed layer has better strength. Creation of defects related to coalescence of the pores is avoided.

The layer epitaxed during this step e) is advantageously made from gallium nitride or indium and gallium nitride.

### Comparative Examples and Illustrative Examples of Various Embodiments

### Comparative Example: Increase in the Thickness of the Layer to be Porosified

In this first example implemented by way of comparison, the following stack was studied (FIG. 5):
sapphire or silicon substrate 114,
layer 111 of nid GaN 3 μm thick,
layer 112 of n-doped GaN to be porosified (doping 6×10¹⁸ at/cm³) 4 μm thick,
layer 124 of nid GaN 100 nm thick.

Mesas of width L were formed in the stack. Each mesa comprises a part of the layer of n-doped GaN and the layer of nid GaN.

The other part of the layer of doped GaN forms part of the base of the structure.

A structure with mesas 3 μm wide and a structure with mesas 5 am wide were manufactured.

The contacts are made on the layer of n-doped GaN at the base of the structure outside the mesas (the contact is represented by an arrow on FIG. 5).

Then the anodising step is implemented.

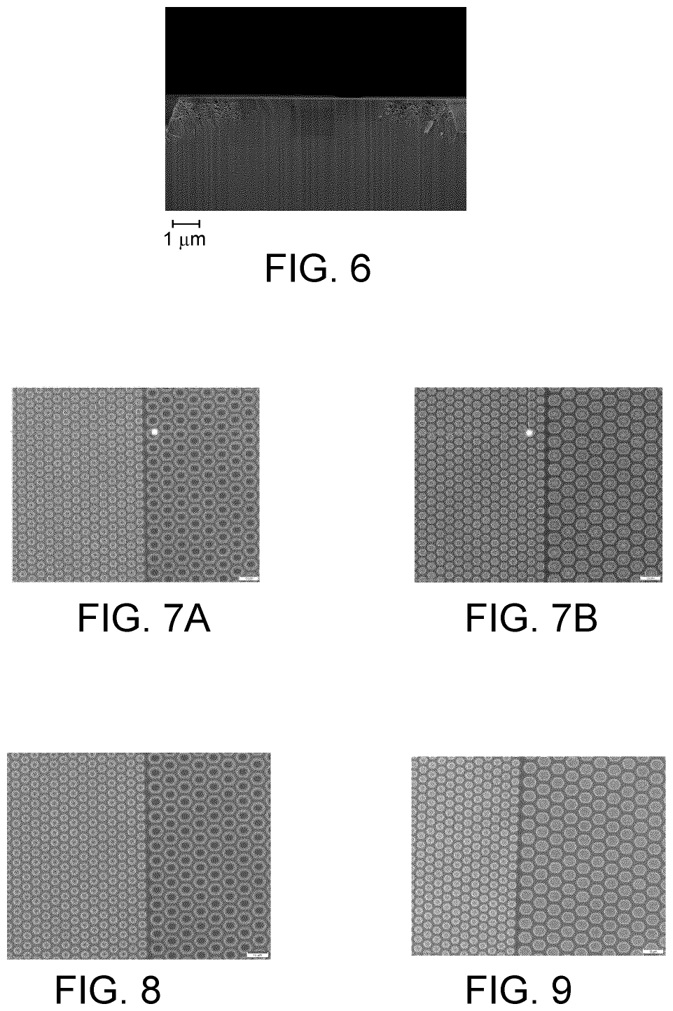

In this configuration, it was observed that the layer 112 that serves to provide the charges is also the origin of electrochemical porosification reactions. As the process continues it loses its conductive properties and the porosification of the mesas stops. At the end of the method, the mesas were observed by scanning electron microscope (FIG. 6) and by black-background optical microscope (FIGS. 7A and 7B): the mesas of the centre of the structure are very partially porosified.

So that it remains integral, the thickness (or height) of the layer 112 was increased.

It was observed that, to be able to porosify the centre of the nid GaN/n-doped GaN mesas (doping of 6×10¹⁸ at/cm³), it is necessary to satisfy the relationship: L<2×a

This is because, if L>2×a, porosification takes place with the same kinetics on the sides of the mesas and on the conductive layer. When the conductive layer porosifies, it can no longer supply the mesas and porosification stops. The mesa is partially porosified: the centre of the mesas is not porosified.

For L<2×a, the mesa is fully porosified but an edge/centre effect of the mesas is still present. In addition, such a configuration can lead to integration problems with respect to the thickness. This is because, to porosify large mesas, the contact layer must be thicker. However, for a silicon substrate, it is not possible to have a thickness of 4 μm, which leads to integration problems.

In the case of GaN/InGaN mesas, the electrolyte infiltrates through the defects (‘V-pits’) in the InGaN layer. Porosification takes place through the latter, thus porosifying the centre of the mesa whatever the values of a and L. It is also possible to have an edge/centre effect of the wafer with incomplete porosification of the mesas located at the centre of the wafer because of the degradation of conductivity of the current-injection layer during the electrochemical polarisation.

### 1^{st} Embodiment: Stack with a Heavily Doped Layer

In this first embodiment, as shown on FIG. 2A, the structure 100 to be porosified is manufactured from a stack comprising successively:
a sapphire substrate 114,
a 4 am first layer 111 of non-doped GaN,
a 600 nm second layer 112 of doped GaN (1×10¹⁸ at/cm³),
an 800 nm third layer 123 of heavily doped GaN (1.5×10¹⁹ at/cm³), and
a 100 nm fourth layer 124 of nid (Al,In,Ga)N.

The mesas 120 are formed in the fourth layer 124 of non-doped or lightly doped (Al,In,Ga)N, the third layer 123 of heavily doped GaN and a part of the second layer 112 of doped GaN (over a thickness of 100 nm).

A structure with mesas 3 μm wide and a structure with mesas 5 μm wide were manufactured. The porosification step is implemented by applying a voltage of 9 V for 500 s (non-pulsed) in an oxalic acid solution (0.3 M).

All the mesas 120 of one and the same wafer are porosified for substrates of small or moderate dimensions. However, for substrates of very large dimensions (typically greater than or equal to 200 mm), complete porosification of all the mesas of one and the same wafer is not assured: those of the edge are fully porosified, whereas those of the centre, far from the contact, are not completely porosified (FIG. 8; on the left the 3 am mesas and on the right the 5 am mesas).

### 2^{nd} Embodiment: Stack with Two Heavily Doped Layers Disposed on Either Side of the Doped Layer

In this other embodiment, as shown on FIG. 3A, the structure 100 to be porosified is manufactured from a stack comprising successively:
a sapphire support layer 114,
a 4 am first layer 111 of non-doped GaN,
a 2 am additional layer 113 of heavily doped GaN (1.5×10¹⁹ at/cm³), referred to as a buried layer,
a 600 nm second layer 112 of doped GaN (1×10¹⁸ at/cm³),
an 800 nm third layer 123 of heavily doped GaN (1.5×10¹⁹ at/cm³), and
a 100 nm fourth layer 124 of nid (Al,In,Ga)N.

The mesas 120 are formed in the fourth layer of non-doped or lightly doped (Al,In,Ga)N, the third layer 123 of heavily doped (Al,In,Ga)N and a part of the second layer of doped GaN (over a thickness of 100 nm).

A structure with mesas 3 μm wide and a structure with mesas 5 am wide were manufactured. The porosification step is implemented by applying a voltage of 9 V (non-pulsed) in an oxalic acid solution (0.9 M) for between 100 and 1000 s. Stoppage of the process is controlled with the drop in current.

With the addition of a buried heavily doped layer 113, the porosification process is rapid and all the mesas of one and the same wafer are fully porosified not only at the edge but also at the centre of the substrate (FIG. 9; on the left the 3 μm mesas and on the right the 5 am mesas).

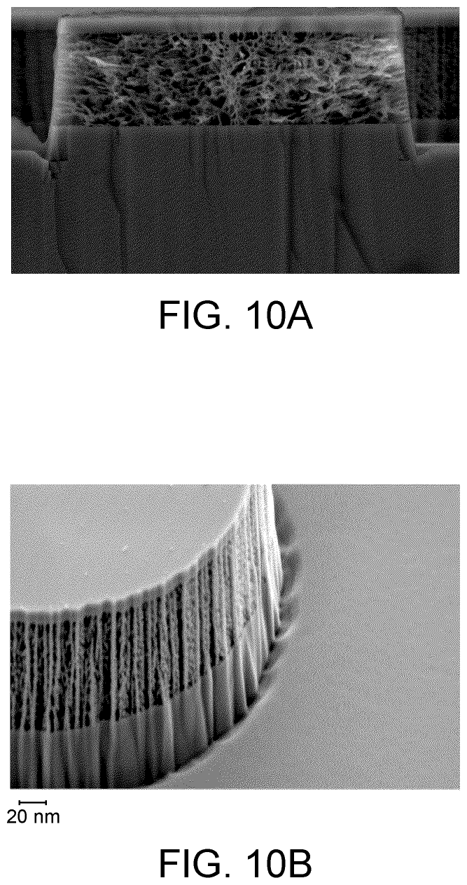

The feet of the mesas are integral (FIGS. 10A and 10B).

### Simulation of the Currents During the Porosification of the Structure of the 2^{nd} Example

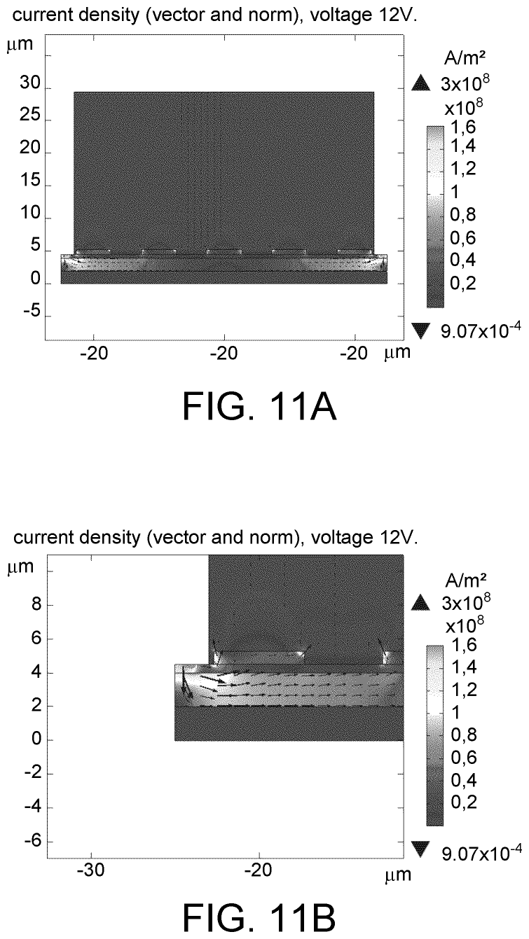

A 50 am diameter stack was simulated. The stacks (thicknesses of the layers and doping) correspond to those of example 2 above. The mesas are 3 am wide. The simulation confirms that the current injected at the periphery passes through the buried layer, which is more heavily doped (FIGS. 11A and 11B). There is thus better distribution of the current in the material.

1. A method for porosifying (Al,In,Ga)N/(Al,In,Ga)N mesas comprising the following steps:
a) providing a structure comprising a base substrate covered with (Al,In,Ga)N/(Al,In,Ga)N mesas,
the base substrate comprising:
a support layer,
a first layer of non-doped GaN, disposed on the support layer,
an additional layer of heavily doped GaN, disposed on the first layer of non-doped GaN,
a second layer of doped GaN, disposed on the additional layer of heavily doped GaN,
the (Al,In,Ga)N/(Al,In,Ga)N mesas comprising:
a third layer of heavily doped (Al,In,Ga)N, and
a fourth layer of non-doped or lightly doped (Al,In,Ga)N,
a part of the second layer of doped GaN being extended in the mesas or a part of the third layer of heavily doped (Al,In,Ga)N being extended in the base substrate,
b) electrically connecting the structure and a counter-electrode to a voltage or current generator,
c) immersing the structure and the counter-electrode in an electrolytic solution,
d) applying a voltage or a current between the structure and the counter-electrode so as to porosify the third layer of heavily doped (Al,In,Ga)N of the mesas.

2. The method according to claim 1, wherein the support layer is a wafer at least 10 cm in diameter and even more preferentially at least 200 mm in diameter.

3. The method according to claim 1, wherein the support layer is made from sapphire or silicon.

4. The method according to claim 1, wherein the fourth layer of non-doped or lightly doped (Al,In,Ga)N is a layer of GaN.

5. The method according to claim 1, wherein the doping level of the third layer of heavily doped (Al,In,Ga)N and/or the doping level of the additional layer of heavily doped GaN is between 5×10¹⁸ at/cm³ and 1.5×10¹⁹ at/cm³.

6. The method according to claim 1, wherein the doping level of the second layer of doped GaN is less than 5×10¹⁸ at/cm³, preferably between 5×10¹⁷ and 2×10¹⁸ at/cm³.

7. The method according to claim 1, wherein the voltage applied is between 3V and 15V, preferably between 8V and 10V.

8. A structure comprising a base substrate covered with porosified (Al,In,Ga)N/(Al,In,Ga)N mesas, the base substrate comprising:
a support layer,
a first layer of non-doped GaN, disposed on the support layer,
an additional layer of heavily doped GaN, disposed on the first layer of non-doped GaN,
a second layer of doped GaN, disposed on the additional layer of heavily doped GaN,
the (Al,In,Ga)N/(Al,In,Ga)N mesas comprising:
a third layer of porosified heavily doped GaN, and
a fourth layer of non-doped or lightly doped (Al,In,Ga)N,
a part of the second layer of doped GaN being extended in the mesas or a part of the third layer of heavily doped (Al,In,Ga)N being extended in the base substrate.

9. The structure according to claim 8, wherein the fourth layer of non-doped or lightly doped (Al,In,Ga)N is a layer of GaN and/or in that the support layer is a wafer at least 200 mm in diameter.
